(19) United States
(12) Patent Application Publication
(10) Pub. No.: US 2008/0242095 A1
(43) Pub. Date: Oct. 2, 2008

(54) Method for forming trench in semiconductor device

(76) Inventors: Ky-Hyun Han, Kyoungki-do (KR); Dong-Hyun Kim, Kyoungki-do (KR)

Correspondence Address: BLAKELY SOKOLOFF TAYLOR & ZAFMAN LLP, 1279 OAKMEAD PARKWAY, SUNNYVALE, CA, 94085-4040, US

(21) Appl. No.: 11/824,054

(22) Filed: Jun. 29, 2007

(30) Foreign Application Priority Data
Mar. 26, 2007 (KR) 10-2007-0029021

(51) Int. Cl. H01L 21/311

(52) U.S. Cl. 438/700; 257/E21.249

(57) ABSTRACT

A method for fabricating a trench in a semiconductor device includes forming a mask pattern over a substrate, and etching the substrate to form a trench with a vertical profile, the etching performed at an etching rate of approximately 40 A/sec or less using an etching gas including a gas generating polymers

### CROSS-REFERENCE TO RELATED APPLICATIONS

The present invention claims priority of Korean patent application number 10-2007-0029021, filed on Mar. 26, 2007, which is incorporated by reference in its entirety.

### BACKGROUND OF THE INVENTION

The present invention relates to a method for fabricating a semiconductor device, and more particularly, to a method for forming a trench in a semiconductor device.

With the ultra-high integration of a semiconductor device, shrinkage of a pattern is demanded. As for the shrinkage of the pattern, a method for forming an isolation structure becomes increasingly important. A local oxidation of silicon (LOCOS) method, which is used for forming an isolation structure, often has a limitation in reducing the width of the isolation structure. Thus, recently a shallow trench isolation (STI) process is normally used for forming the isolation structure.

According to the STI process, a substrate is etched to form a trench, which is, in turn, filled with a material to form an insulating structure. However, with the high integration of the device, the width of the trench is relatively decreased to a greater extent than the depth thereby. More particularly, during forming of the trench, as a bowing occurs on a profile of the sidewalls of the trench due to a change in etching characteristics with the reduction of the pattern size (see FIG. 1A), it is often hard to fill a gap of the trench with the insulation structure.

As FIG. 1B illustrates, with increasing a gradient of the sidewalls of the trench, the gap-fill characteristics for the trench may be improved. However, in the case of increasing the gradient of the sidewalls of the trench, a cuspidate-shaped horn is more likely to form on the boundary between the isolation structure and a recess, when recess gates are formed. The horn may deteriorate electrical characteristics of the device. For example, a threshold voltage (Vt) may decrease. Thus, controlling the bowing of the sidewalls of the trench with a vertical profile is demanded for improving the gap-fill characteristics for the insulation structure and simultaneously preventing deterioration of the electrical characteristics of the device.

The method for forming the trench by etching the substrate can be applied to other methods. Forming a recess gate by filling the trench formed by etching the substrate with a conductive structure for a gate electrode is one example of such application, and forming a storage node by filling the trench formed by etching the substrate with a conductive structure for a storage node is another example. Forming the trench by etching the substrate to a given thickness is generally essential for the above examples. The sidewalls of the trench need to have a vertical profile for various reasons when the recess gates or storage nodes are formed.

### SUMMARY OF THE INVENTION

Embodiments of the present invention are directed toward providing a method for fabricating a semiconductor device with a trench to control an occurrence of bowing on sidewalls of the trench and form the sidewalls of the trench to have a vertical profile. The introduced method can be applied for fabricating various semiconductor devices, such as forming of isolation structure between devices, thereby improving characteristics of the device.

In accordance with one embodiment of the present invention, there is provided a method of fabricating a trench in a semiconductor device. The method includes forming a mask pattern over a substrate, and etching the substrate to form a trench with a vertical profile, the etching performed at an etching rate of approximately 40 Å/sec or less using an etching gas including a gas generating polymers.

In accordance with one embodiment of the present invention, there is provided a method of fabricating a trench in a semiconductor device. The method includes forming a mask pattern over a substrate, and etching the substrate to form a trench for isolation with a vertical profile, the etching performed using a gas generating polymers as an etching gas.

### BRIEF DESCRIPTION OF THE DRAWINGS

FIGS. 1A and 1B illustrate sectional views of trenches to show limitations occurring in fabricating a typical semiconductor device.

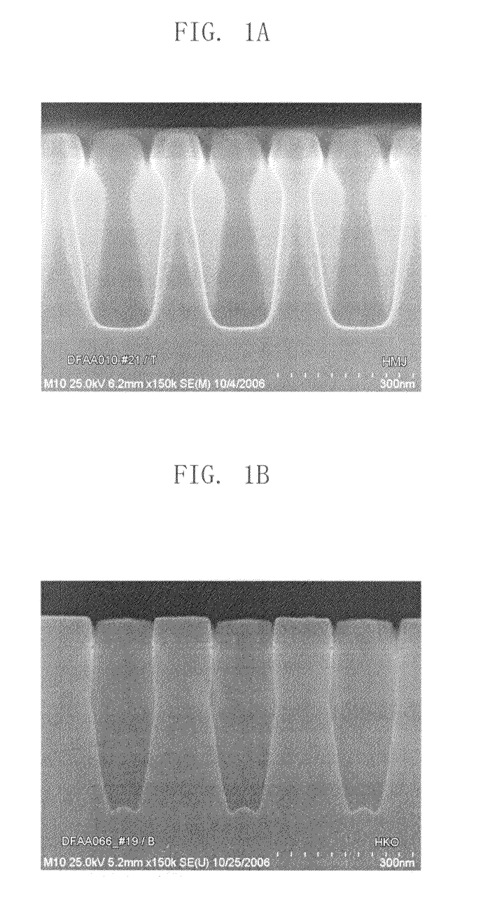

FIGS. 2A and 2B are sectional views illustrating a method for forming a trench in accordance with an embodiment of the present invention.

FIG. 3 illustrates sectional views of trenches to show profile changes in the trenches as temperature decreases at a constant flow rate of HBr gas.

FIG. 4 illustrates sectional views of trenches to show profile changes in the trenches as a flow rate of Cl₂ gas, which increases an etching rate of a substrate, increases at a constant flow rate of HBr gas.

FIG. 5 illustrates sectional views of trenches to show profile changes in the trenches as a flow rate of O₂ gas increases at a constant flow rate of HBr gas.

FIG. 6 illustrates sectional views of trenches to show profile changes in the trenches as a flow rate of SF₆ gas or NF₃ gas decreases at a constant flow rate of HBr gas.

FIG. 7 illustrates a sectional view of a semiconductor device with trenches in accordance with an embodiment of the present invention.

### DESCRIPTION OF SPECIFIC EMBODIMENTS

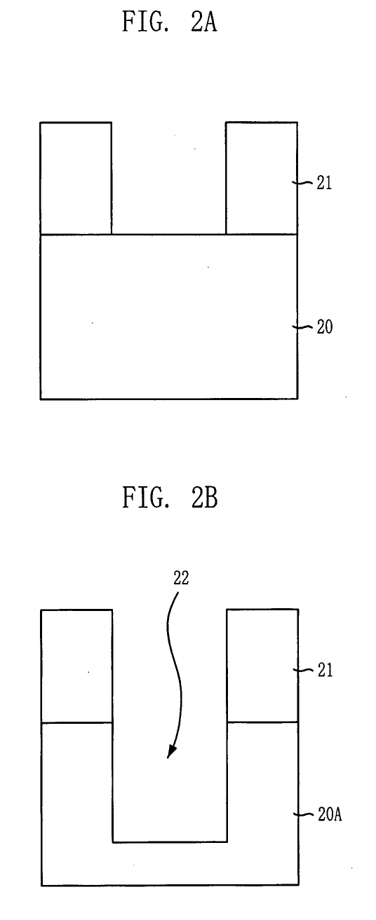

FIGS. 2A and 2B are sectional views illustrating a method for forming a trench in accordance with an embodiment of the present invention. Referring to FIG. 2A, a hard mask pattern 21 exposing a trench region is formed on a substrate 20 (e.g., a silicon substrate). The hard mask pattern 21 includes one selected from a group consisting of an oxide-based material, a nitride-based material, a silicon nitride-based material, and a combination thereof.

Referring to FIG. 2B, a trench 22 for isolation is formed by etching the substrate 20 to a given depth using the hard mask pattern 21 as an etching mask. The trench 22 is formed, as abovementioned, such that sidewalls of the trench 22 has a vertical profile without generating a bowing thereon, so as to improve a gap-fill characteristic, for insulation and simultaneously prevent deterioration of electrical characteristics of the device.

The prevention can be achieved by performing of the bowing generation on sidewalls of the trench 22, the above etching using an etch gas including a large amount of a gas that can generate polymers. More particularly, etching the substrate 20 proceeds with using HBr gas as the polymer generating gas. The HBr gas flows at a rate of approximately 200 sccm to 600 sccm. At this time, an amount of polymers generated can be controlled by adjusting a temperature of an electro static chuck (ESC) on which the substrate 20 is mounted. Reference numeral 20A presents a patterned substrate.

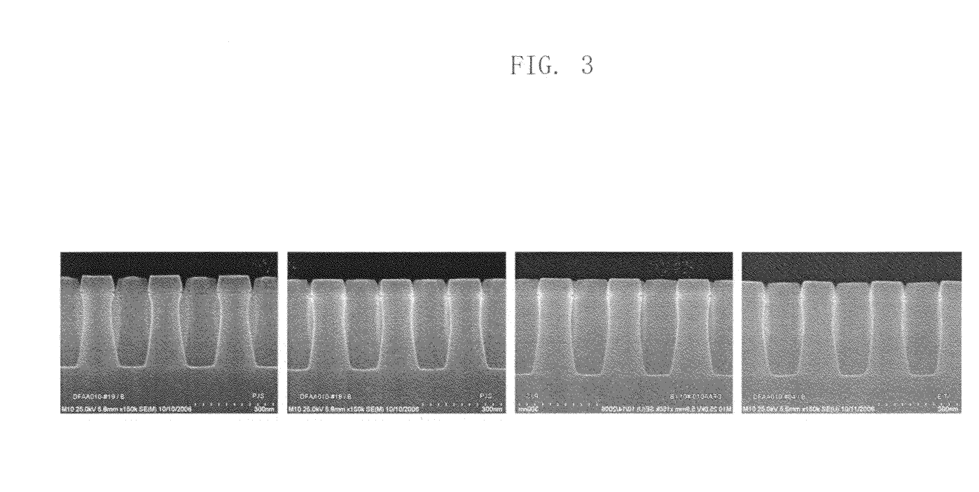

FIG. 3 illustrates sectional views of trenches to show profile changes in the trenches as a temperature of an ESC decreases at a constant flow rate of HBr gas. As the temperature of the ESC decreases (specifically, going to the right side of the figure), the bowing of the trenches is less likely to occur. Thus, decreasing the temperature of the ESC on which the substrate 20 is mounted is desirable. More particularly, a desirable temperature of the ESC, which makes it possible to generate a certain amount of polymers that disallows the generation of the bowing on sidewalls of the trench while providing a vertical profile of the sidewalls of the trench, is in a range of approximately 10° C. to 70° C.

For forming the sidewalls of the trench to have a vertical profile, the substrate 20 needs to be etched at a low etching rate in addition to the use of an etching gas including a large amount of a gas that can generate polymers. Since, when the substrate 20 is etched at a high etching rate, a gradient of the sidewalls of the trench 22 generally increases.

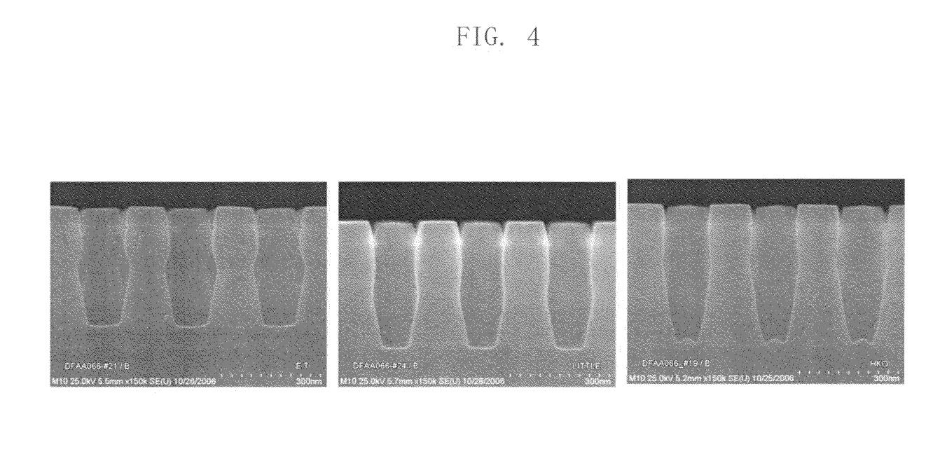

FIG. 4 illustrates sectional views of trenches to show profile changes in the trenches as a flow rate of Cl₂ gas, which increases an etching rate of a substrate, increases at a constant flow rate of HBr gas. As a flow rate of Cl₂ gas increases (specifically, going to the right side of the figure), the etching rate of the substrate increases and a gradient of sidewalls (especially, the bottom sidewalls of the trench) of the trench increases. At this time, the etching rate is in a range of approximately 40 Å/sec to 60 Å/sec.

Therefore, the etching rate of the substrate 20 needs to be decreased to approximately 40 Å/sec or less. For instance, the etching rate ranges between approximately 15 Å/sec and 30 Å/sec. For satisfaction of such a low etching rate, the etching is performed under conditions of: a pressure ranging from approximately 10 mTorr to 50 mTorr, a source power ranging from approximately 300 W to 600 W, and a bottom power ranging from approximately 0 W to 200 W. Furthermore, in the case of adding O₂ gas to the above etching gas or decreasing a flow rate of SF₆ gas or NF₃ gas normally used in etching a substrate, the generation of the bowing on the sidewalls of the trench 22 can be controlled, and the etching rate of the substrate 20 can be decreased. As a result, the gradient of the bottom sidewalls of the trench can be decreased.

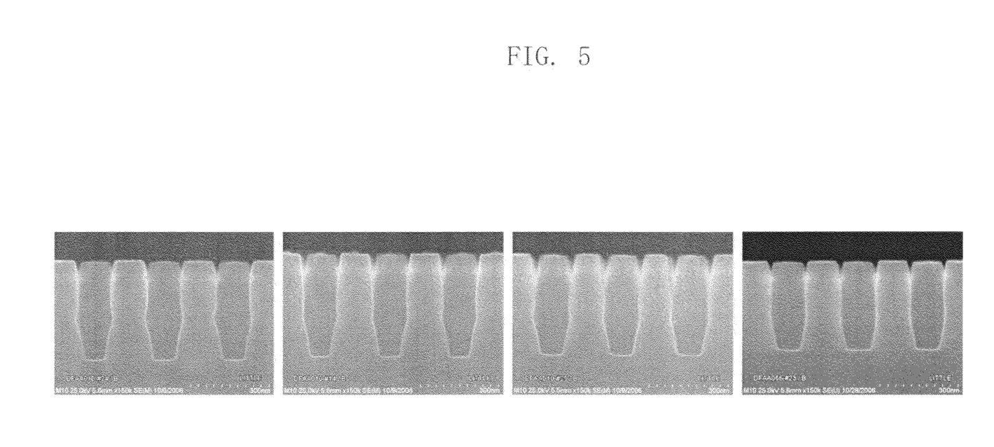

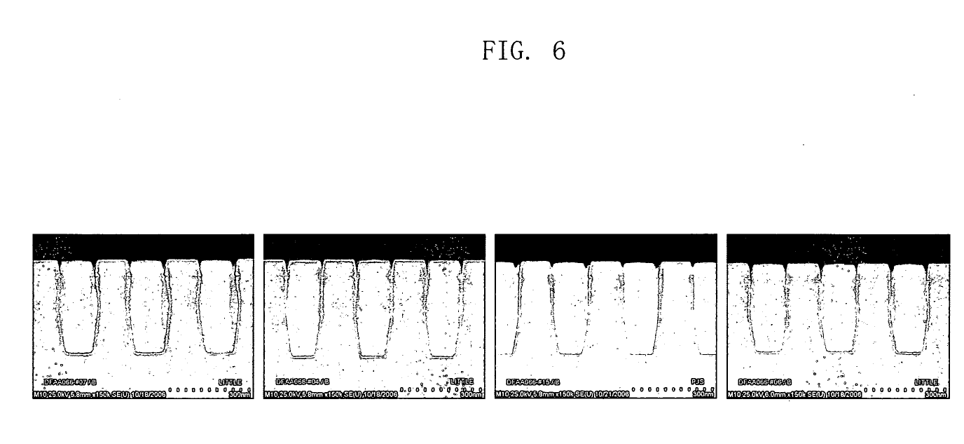

FIG. 5 illustrates sectional views of trenches to show profile changes in the trenches as a flow rate of O₂ gas increases at a constant flow rate of HBr gas. FIG. 6 illustrates sectional views of trenches to show profile changes in the trenches as a flow rate of SF₆ gas or NF₃ gas decreases at a constant flow rate of HBr gas. As the flow rate of O₂ gas increases more or the flow rate of SF₆ or NF₃ gas decreases more (specifically, going to the right side of the figures), the bowing on the bottom sidewalls of the trench is less frequently generated. In particular, the gradient of the bottom sidewalls of the trench decreases. At this time, a desirable flow rate of O₂ gas is in a range of approximately 15 sccm to 30 sccm, a desirable flow rate of SF₆ gas is in a range of approximately 10 sccm to 30 sccm, and a desirable flow rate of NF₃ gas is in a range of approximately 20 sccm to 60 sccm.

In the case of forming the trench 22 by etching the substrate 20 under the abovementioned conditions, the sidewalls of the trench can be formed to have a vertical profile without the generation of the bowing. Subsequently, although not illustrated, the isolation structure is filled in the trench as a succeeding process.

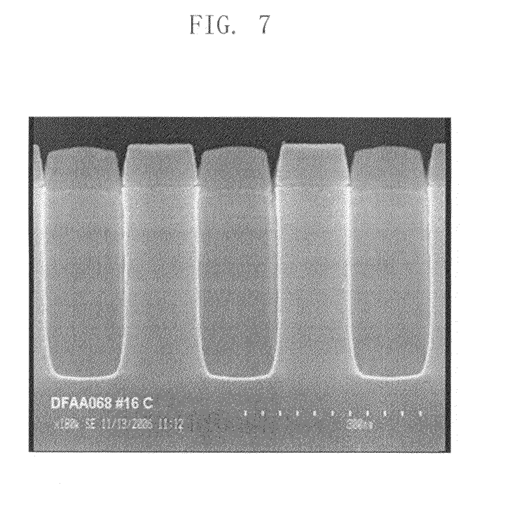

FIG. 7 illustrates a sectional view of a semiconductor device with trenches in accordance with an embodiment of the present invention. Trenches are formed to have a vertical profile. Thus, an isolation structure can be easily gap-filled in the trenches. In the case of forming recess gates as a succeeding process, the height of a horn formed on the boundary between the isolation structure and recesses can be decreased.

Even though applying the formation of the trench with the vertical profile to form the isolation structure is described in the present embodiment, it should not be construed as a limitation. For example, forming the trench with the vertical profile can be applied for forming a trench for a storage node or a recess gate.

The abovementioned method introduces the formation of a semiconductor device in accordance with various embodiments of the present invention trench by etching a substrate while controlling the generation of the bowing on the sidewalls of the trench and simultaneously providing a vertical profile of the sidewalls of the trench. This method can be applied for fabricating various semiconductor devices, such as forming of an isolation structure between devices. This method can contribute to improving characteristics of the device.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a trench in a semiconductor device, the method comprising:
forming a mask pattern over a substrate; and
etching the substrate to form a trench with a vertical profile, the etching performed at an etching rate of approximately 40 Å/sec or less using an etching gas including a gas generating polymers.

2. The method of claim 1, wherein the gas generating the polymers includes HBr gas.

3. The method of claim 2, wherein the HBr gas flows at a rate of approximately 200 sccm to 600 sccm.

4. The method of claim 1, wherein if the substrate is placed on an electro static chuck, etching the substrate further comprises adjusting a temperature of the electro static chuck(ESC).

5. The method of claim 4, wherein the temperature of the ESC ranges from approximately 10° C. to 70° C.

6. The method of claim 1, wherein the etching rate of the etching gas ranges approximately 15 Å/sec to 30 Å/sec.

7. The method of claim 6, wherein the etching the substrate is performed applying a pressure ranging from approximately 10 mTorr to 50 mTorr.

8. The method of claim 6, wherein the etching the substrate is performed applying a source power ranging from approximately 300 W to 600 W.

9. The method of claim 6, wherein the etching the substrate is performed applying a bottom power ranging from approximately 0 W to 200 W.

10. The method of claim 6, wherein the etching gas further comprises O₂ gas.

11. The method of claim 10, wherein the O₂ gas flows at a rate of approximately 15 sccm to 30 sccm.

12. The method of claim 6, wherein the etching gas further includes SF₆ gas and NF₃ gas.

13. The method of claim 12, wherein the SF₆ gas flows at a rate of approximately 10 sccm to 30 sccm and the NF₃ gas flows at a rate of approximately 20 sccm to 60 sccm.

14. The method of claim 1, wherein the trench comprises one of a trench for isolation, a trench for a recess gate and a trench for a storage node.

15. The method of claim 1, wherein the mask pattern includes one of an oxide-based material, a nitride-based material, a silicon nitride-based material, and a combination thereof.

16. A method for fabricating a trench in a semiconductor device, the method comprising:
forming a mask pattern over a substrate; and
etching the substrate to form a trench for isolation with a vertical profile, the etching performed using a gas generating polymer as an etching gas.

17. The method of claim 16, wherein the etching is performed at an etching rate of approximately 40 Å/sec or less.

18. The method of claim 17, wherein the mask pattern includes a nitride-based material.
